(19) United States
(12) Patent Application Publication
(10) Pub. No.: US 2016/0126165 A1
(43) Pub. Date: May 5, 2016

(54) METHOD OF CONNECTING A SUBSTRATE AND CHIP ASSEMBLY

(71) Applicant: Infineon Technologies AG, Neubiberg (DE)

(72) Inventors: Paul FRANK, Villach (AT); Alexander HEINRICH, Bad Abbach (DE); Michael JUERSS, Regenstauf (DE); Chiong Yong TAY, Johor (MY)

(21) Appl. No.: 14/927,561

(22) Filed: Oct. 30, 2015

(30) Foreign Application Priority Data
Oct. 30, 2014 (DE) 10 2014 115 770.2

(51) Int. Cl. H01L 23/495; H01L 21/78; H01L 23/00; H01L 21/48

(52) U.S. Cl. CPC H01L 23/49513; H01L 21/4825; H01L 21/78; H01L 24/32; H01L 24/83; H01L 2224/3207; H01L 2224/32258; H01L 2224/32502; H01L 2924/014

(57) ABSTRACT

A method of connecting a substrate is provided, wherein the substrate may include a first main surface and a second main surface opposite the first main surface. The method may include forming at least one protrusion on the first main surface of the substrate, forming a fixing agent over the first main surface of the substrate and over the at least one protrusion; and arranging the substrate on a carrier. The at least one protrusion may contact a surface of the carrier and may be configured to keep the first main surface of the substrate at a distance to the contacted surface of the carrier corresponding to a height of the protrusion, thereby forming a space between the first main surface of the substrate and the carrier. During the arranging the substrate on the carrier, at least a part of the fixing agent formed over the at least one protrusion may be displaced into the space between the first main surface of the substrate and the carrier.

### CROSS-REFERENCE TO RELATED APPLICATION

This application claims priority to German Patent Application Serial No. 10 2014 115 770.2, which was filed Oct. 30, 2014, and is incorporated herein by reference in its entirety.

### TECHNICAL FIELD

Various embodiments relate generally to a method of connecting a substrate and to a chip assembly.

### BACKGROUND

Mounting a substrate, e.g. a chip, on a carrier using a fixing agent may lead to a squeeze-out of at least a portion of the fixing agent from a space between the chip and the carrier. This may make it necessary to reserve room on the carrier, e.g. around the chip, for the squeezed-out fixing agent.

### SUMMARY

A method of connecting a substrate is provided. The substrate may include a first main surface and a second main surface opposite the first main surface. The method may include forming at least one protrusion on the first main surface of the substrate, forming a fixing agent over the first main surface of the substrate and over the at least one protrusion, and arranging the substrate on a carrier. The at least one protrusion may contact a surface of the carrier and may be configured to keep the first main surface of the substrate at a distance to the contacted surface of the carrier corresponding to a height of the protrusion, thereby forming a space between the first main surface of the substrate and the carrier. During the arranging the substrate on the carrier, at least a part of the fixing agent formed over the at least one protrusion may be displaced into the space between the first main surface of the substrate and the carrier.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A and FIG. 1B each show a method of connecting a die to a carrier;

FIGS. 2A to 2D show a method of connecting a substrate according to various embodiments as cross-sectional views at various stages of the method;

FIG. 3 shows an analogous example of a substrate to be connected using a method of connecting a substrate according to various embodiments;

FIG. 4 shows a schematic top view of a substrate to be connected using a method of connecting a substrate according to various embodiments;

FIG. 5 shows a schematic top view of substrate to be connected using a method of connecting a substrate according to various embodiments;

FIG. 6 shows two photographs of top views of substrates comparing a substrate connected using a method of connecting a substrate according to various embodiments to a substrate connected using a conventional method; and

FIG. 7 shows a process flow for a method of connecting a substrate according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

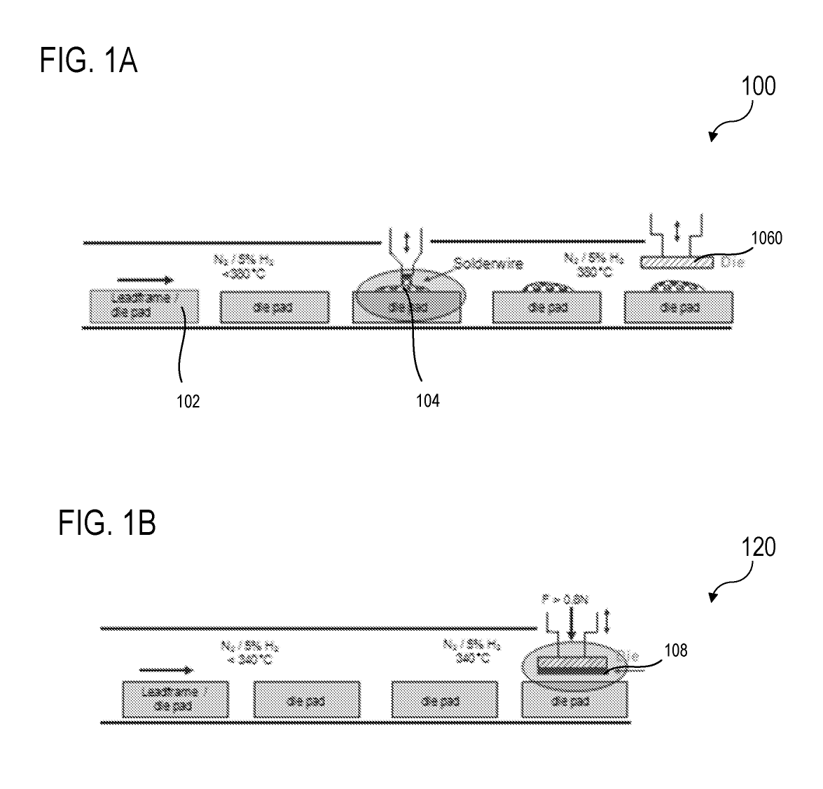

As shown in FIG. 1A and FIG. 1B, dies 1060 (also referred to as chips 1060) may be connected to a carrier 102 using a fixing agent, for example using a soldering process. As shown in FIG. 1A, a soft soldering, e.g. a soldering with a solder paste 104 or a glue bonding with a glue 104, may be used for connecting the chip 1060 to the carrier 102. An amount of the solder paste or glue 104 that may for example be dispensed on the carrier 102 may be relatively large, and/or a three-dimensional position and/or orientation of the chip 1060 above the carrier 102 and/or a force applied for pressing the chip 1060 onto the carrier 102 may not be well controlled, such that a pressing of the chip 1060 onto the carrier 102 may lead to at least a part of the solder paste or glue 104 being squeezed out from a space between the chip 1060 and the carrier 102. The squeezed-out amount of material may also be referred to as squeeze-out. Instead of the soft soldering, a diffusion soldering process (as shown in FIG. 1B) may be applied. For a diffusion soldering, a diffusion solder 108 may be formed as a metallization layer 108, e.g. a backside metallization 108, of the chip 1060. An amount of the diffusion solder may thus be relatively well-controlled. Thereby, the squeeze-out as compared with the soft soldering and a corresponding space to be reserved around the chip may be reduced. For example, attaching a chip to a package with a standard die pad size, e.g. to the CoolMOS C6 in TO220 package using soft solder, a size of the largest possible chip that may be used is about 30.24 mm². Using a gold-tin (AuSn) diffusion solder instead, the size of the largest possible chip that may be used increases to about 34.42 mm².

The increase of the chip size may furthermore improve a performance of the chip. For example, the size increase in the above example may lead to a decrease of an on-state resistance R_{DS(on)} of the chip by about 10%, e.g. from about 72 mΩ to about 65 mΩ.

However, the position/orientation of the chip 106 relative to the carrier 102 and/or the force applied for pressing the chip 106 onto the carrier 102, despite attempts to control these parameters form minimizing the squeeze-out, may suffer from the same limitations as for the soft soldering. As a consequence, the squeeze-out may still be relatively large and may require a relatively large amount of space on the carrier 102 around the chip 106 to be reserved.

Reducing the squeeze-out even further would allow to reduce the space on the carrier reserved for receiving the squeeze-out even more, and to use the saved space for increasing the size of the chip to be mounted, thereby improving the chip performance, e.g. decrease the on-state resistance of the chip and decreasing the package size for a given chip.

In various embodiments, on a surface of a substrate to be attached, e.g. to a carrier, at least one protrusion may be formed. When the substrate is attached to the carrier, the protrusion may act as a spacer element preventing the substrate from getting too close to the carrier, thereby creating a space between the substrate and the carrier in which at least a part of a fixing agent used for attaching the chip to the carrier may be received. Thereby, the fixing agent received in the space may be prevented from being squeezed out from between the substrate and the carrier.

The at least one protrusion may also be referred to as a structure, the substrate with the at least one protrusion as a structured substrate and the surface of the substrate with the at least one protrusion formed on as a structured surface. A part of the structured surface that is not part of the protrusion may be referred to as the recessed surface.

In various embodiments, the at least one protrusion may be formed as an extended structure, for example as a wall or as a plurality of walls. The wall and/or the plurality of walls may define at least one recess within and/or between them. In various embodiments, a wall may be formed near a circumference of the substrate. The wall may form a closed, ring-like structure (ring-like may be understood as referring to a feature of the structure of having its two ends coincide, not to the structure being circular (even though it may be circular)). Within the ring-like structure, a recess may be formed. In various embodiments, the at least one protrusion may be formed as the plurality of walls, e.g. as walls arranged in a regular fashion, e.g. as a waffle pattern, e.g. as a lattice or a waffle pattern covering essentially the whole structured surface of the substrate.

In various embodiments, the protrusion being formed near the circumference of the substrate may lead to a situation in which, during an arranging of the substrate on the carrier, the protrusion may make a first contact with the carrier, even if the substrate is inclined with respect to the carrier. Furthermore, if the protrusion is formed along the circumference of the substrate, the protrusion may act as a barrier that may inhibit a lateral movement of the fixing agent out from between the substrate and the carrier. As a consequence, less material may be able to contribute to the squeeze-out.

In various embodiments, a metal may be arranged over the structured surface of the substrate, for example a metal layer may be formed over the structured surface of the substrate. The metal, e.g. the metal layer, may be formed on, e.g. cover, the at least one protrusion and the recessed surface. The metal may, in various embodiments, include or essentially consist of a solder, e.g. a diffusion solder, for example a gold-tin-solder (AuSn) or a tin-silver-solder (SnAg). In various embodiments, the metal, e.g. the metal layer, may be formed with a thickness that may be sufficient to fill up the at least one recess. In other words, a thickness of the metal, e.g. the metal layer, may be about the same as or larger than a height of the at least one protrusion.

In various embodiments, the metal may be a fixing agent. In other words, the metal, e.g. the metal layer, may be configured to fix the structured surface of the substrate, e.g. a first main surface of the substrate, on which the protrusion may be formed, to the carrier.

The fixing agent, and possibly the substrate and/or the carrier, may be heated, for example heated to a temperature that is higher than a melting point of the fixing agent. In other words, the metal, e.g. the solid metal, formed on the structured surface of the substrate may be turned into a liquid before arranging the substrate on the carrier.

In various embodiments, the substrate may be arranged on the carrier, for example with the structured surface of the substrate facing the carrier. The at least one protrusion may contact a surface of the carrier and may be configured to keep the surface of the substrate on which the protrusion is formed at a distance to the contacted surface of the carrier. The distance between the surface of the substrate on which the protrusion is formed and the contacted surface of the carrier may correspond to a height of the protrusixon, at least at a point where the protrusion contacts the carrier. By keeping the surface of the substrate on which the protrusion is formed and the contacted surface of the carrier at a distance from each other, a space may be formed between them.

During the arranging the substrate on the carrier, at least a part of the fixing agent formed over the at least one protrusion may be displaced into the space between the first main surface of the substrate and the carrier. In other words, when the substrate is arranged on the carrier, e.g. pressed onto the carrier in a state when the fixing agent may be liquid, e.g. molten, at least a part of the fixing agent that may be arranged over the plurality of protrusions may be moved laterally, e.g. by the force pressing the substrate on the carrier. The part of the fixing agent may for example be moved to the space formed between the substrate and the carrier.

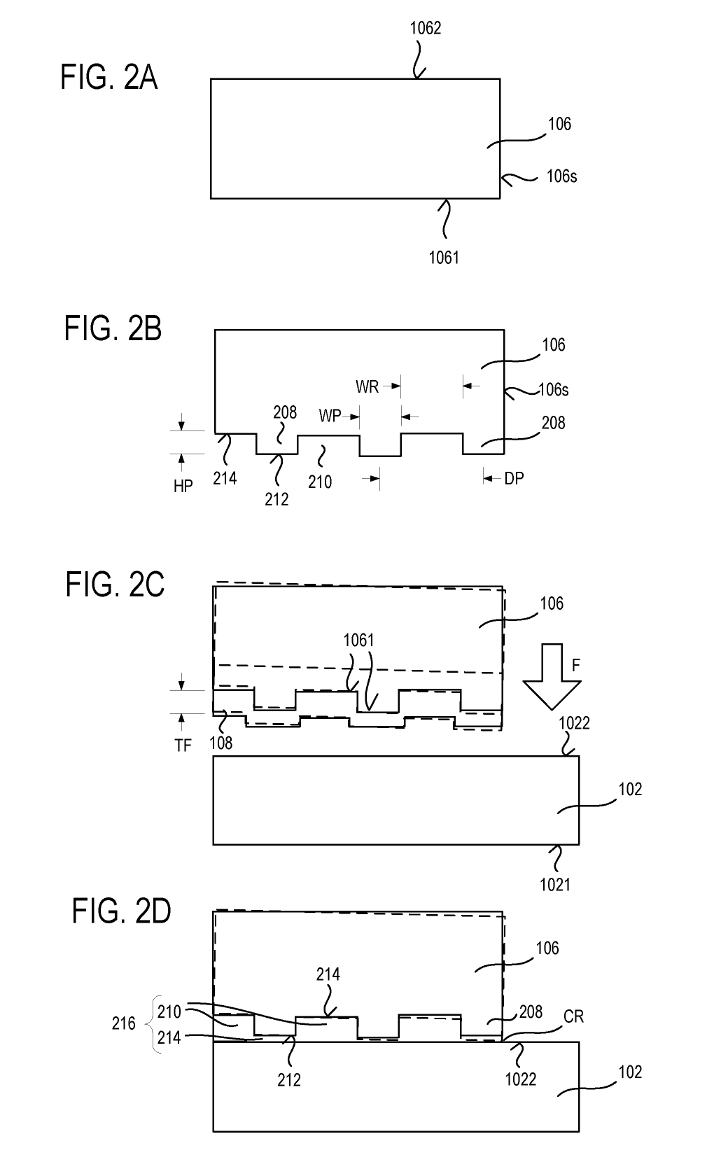

FIG. 2A to FIG. 2D show a method of connecting a substrate according to various embodiments as cross-sectional views at various stages of the method.

As shown in FIG. 2A, a substrate 106 may have a first main surface 1061, which may also be referred to as the back surface 1061, and a second main surface 1062, which may also be referred to as the front surface 1062, opposite the first main surface 1061. A side of the substrate 106 that the first main surface 1061 may be located on, may be referred to as the first side or the back side. A side of the substrate 106 that the second main surface 1062 may be located on, may be referred to as the second side or the front side. The first main surface 1061 and the second main surface 1062 may be connected by side surfaces 106s of the substrate 106.

In various embodiments, the substrate 106 may include or essentially consist of a semiconductor material. The substrate 106 may for example include at least one material from a group of semiconductor materials consisting of silicon, germanium, gallium arsenide, indium antimonide, zinc selenide, and cadmium sulfide, or any other from the group of III-V or II-VI compound semiconductors. The substrate 106 may for example be a chip 106, e.g. a high performance chip 106, a power chip 106, or a wafer 106.

In various embodiments, the substrate 106 may include or essentially consist of a conductive material, for example a metal. The substrate 106 may for example include at least one material from a group of semiconductor materials essentially consisting of copper, aluminum, nickel, a copper alloy, a nickel alloy and an aluminum alloy. The substrate 106 may for example be a lead frame 106.

In various embodiments, the substrate 102 may include or essentially consist of a dielectric material. The substrate 102 may for example include at least one dielectric material from a group of dielectric materials consisting of ceramics and a polymer.

In various embodiments, as shown in FIG. 2B, at least one protrusion 208 may be formed on the first main surface 1061 of the substrate 106. The at least one protrusion 208 may have a height HP in a range from about 0.5 μm to about 2 μm, for example about 1 μm. The at least one protrusion may have a width in a range from about 50 μm to about 200 μm, for example about 100 μm. The first main surface 1061 of the substrate 106 including the at least one protrusion may be referred to as the structured surface 1061 of the substrate 106. The structured surface 1061 may include a contact surface 212 on the at least one protrusion 208, with which the protrusion 208 may contact a carrier 102, at least one recessed surface 214 outside the at least one protrusion 208, and side surfaces of the protrusion 208 between the contact surface 212 and the recessed surface 214.

In various embodiments, the at least one protrusion 208 may be shaped as at least one wall 208, for example as a wall 208 formed at or near a circumference of the substrate 206. In other words, the at least one protrusion 208 may be formed on the first main surface 1061 of the substrate 106 along at least one edge, for example along all edges, of the substrate 106, for example directly at the edge or edges of the substrate 106, or essentially parallel to the edge with a distance from the edge of the substrate 106, for example with a small distance in a range from about 5 μm to about 20 μm, e.g. about 10 μm.

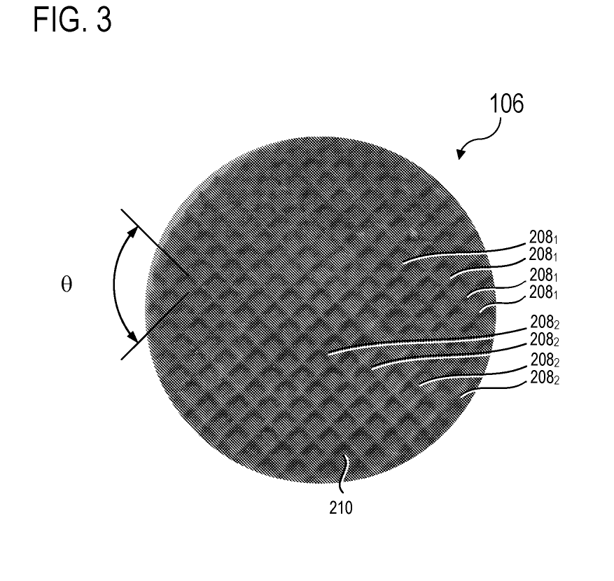

The at least one protrusion 208 may be shaped as a plurality of walls 208 that may be arranged as a grid 208. In other words, the at least one protrusion 208 may include a first set of walls, for example a set of essentially parallel walls, and a second set of walls, for example a set of essentially parallel walls arranged at an angle, e.g. at an essentially right angle, to the first set of walls and intersecting with the first set of walls (see also FIG. 3 to FIG. 5).

In various embodiments, the at least one protrusion 208 may be shaped as a wall or a plurality of walls 208 that may be arranged as a ring, for example a rectangular ring enclosing a rectangular area, or as a plurality of concentric rings, e.g. concentric rectangular rings.

In various embodiments, the at least one protrusion 208 may have any other shape. It may for example be shaped as a pin or a plurality of pins, a combination of walls and pins, circular circles, only one set of essentially parallel walls, etc.

For example in a case where the plurality of protrusions 108 is formed, e.g. the grid structure, or where one protrusion 108 forms a structure with joined ends, e.g. formed like the (not necessarily circular) ring or the plurality of (e.g. concentric) rings, by forming the at least one protrusion 208, at least one recess 210 may be formed on the first main surface 1061 of the substrate 106. The at least one recess 210 may be defined, e.g. bordered, by the at least one protrusion 208, for example between the walls of the grid, between two of the concentric rings, etc.

In various embodiments, a depth of the at least one recess 210 may correspond to the height HP of the protrusion 208. A width and a length of the recess 210 may be in a range from about 100 μm to about 1 mm, for example in a range from about 200 μm to about 600 μm, e.g. from about 400 μm to about 500 μm. The width of the recess 210 may be different from the length of the recess 210.

A ratio of the width of the at least one protrusion 208 to the width and/or the length of the recess 210 may be in a range from about 1/20 to about 1/5, for example around 1/10. For example, the width of the protrusion may be around 50 μm and the width of the recess 210 may be around 500 μm, resulting in the ratio of the width of the at least one protrusion 208 to the width of the recess 210 of around 1/10.

The at least one protrusion 208 may be deposited on the first main surface 1061 of the substrate 106, for example by chemical vapor deposition or by electroplating. In that case, the at least one protrusion may be formed in an additional level over the first main surface 1061 of the unstructured, original first main surface 1061 of the substrate 106. In other words, the recessed surface 214 may be formed by a part of the original first main surface 1061 of the substrate 106.

The at least one protrusion may be formed by etching the first main surface 1061 of the substrate 106, for example dry ecthing or wet etching, for example using a mask. The etching may be used to remove some material from the first main surface 1061 of the substrate, such that the at least one protrusion 208 may remain.

As shown in FIG. 2C, in various embodiments, a fixing agent 108 may be formed over the first main surface 1061 of the substrate 106. The fixing agent 108 may be formed over the protrusion 108 and over the recessed surface 214. The fixing agent 108 may for example cover the complete first main surface 1061 of the substrate 106, for example as a layer of fixing agent 108.

In various embodiments, the fixing agent 108 may include or essentially consist of any material that may be configured to be viscous, e.g. liquid, during the arranging the substrate 106 on the carrier 102, and that may thereafter, e.g. after solidifying, fix the substrate 106 to the carrier 102.

The fixing agent 108 may include or essentially consist of a solder 108, e.g. a diffusion solder 108. The solder 108 may for example include or essentially consist of at least one solder of a group of solders consisting of Sn, In, Zn, Sn, Bi, Ga or a binary combination of these like AuSn, SnAg, InSn, AuIn, ZnSn, BiZn, BiSn, possibly with trace amounts of additional 3^{rd}, 4^{th} or 5^{th} elements.

The fixing agent 108 may include or essentially consist of an adhesive 108, for example a glue, e.g. an electrically and/or thermally conductive glue 108, for example a wafer backside coating glue.

The fixing agent 108 may include or essentially consist of a solder paste 108.

In various embodiments, between the fixing agent 108 and the substrate 106, a material or a plurality of materials, e.g. one or more layers, may be arranged (not shown). The material(s) may for example include or essentially consist of a first material, e.g. a contact layer, formed on the substrate 106. For example in a case where the substrate 106 includes or essentially consists of a semiconductor material, the first material, e.g. the contact layer, may be configured to improve a contact between the substrate 106 and a second material, e.g. a second layer, formed above the first material, e.g. the fixing agent 108 or a bather layer. The second material, e.g. the barrier layer, may be configured to preventing a diffusion, e.g. from the substrate 106 and/or the first layer towards the fixing agent 108 or in the reverse direction. The first layer may for example include or essentially consist of arsenic (As), gold (Au), aluminum (Al), titanium (Ti), and/or chromium (Cr). The second layer may for example include or essentially consist of titanium (Ti), tungsten (W), tungsten titanium alloy (TiW), titanium nitride (TiN), tantalum (Ta), tantalum nitride (TaN), cobalt (Co) and the like.

In various embodiments, the fixing agent 108 may have a thickness in a range from about 0.5 μm to about 2 μm, e.g. around 1 μm.

In various embodiments, a thickness of the fixing agent 108, e.g. of the layer of fixing agent 108, may be chosen such that a volume of the fixing agent 108 arranged over the first main surface 1061 may correspond to a total volume of the at least one recess 210. V_{FIX}=TF×A_{MS1}, V_{REC,total}=n×V_{REC}, e.g. n×A_{REC}×HP. V_{FIX} may be the volume of the fixing agent, TF may be the thickness of the fixing agent 108, A_{MS1} may be an area of the first main surface 1061, V_{REC,total} may be the total volume of the at least one recess 210, n may be the number of recesses (in this example, it is assumed that n essentially identical recesses 210 may be formed. More generally, V_{REC,total}=ΣV_{REC, i} for i=1 to n), A_{REC} may be an area of an individual recess 210, and HP may be the height of the protrusion 208 (which may correspond to the depth of the recess 210). If the volume of the fixing agent 108 corresponds to a total volume of the at least one recess 210, the thickness TF of the fixing agent 108 may be TF=n×A_{REC}×HP/A_{MS1}. This thickness TF of the fixing agent 108 may, after the fixing the substrate 106 to the carrier 102 as shown in FIG. 2D, lead to a situation in which the at least one recess 210 may be filled, e.g. completely filled, with the fixing agent 108, whereas essentially no fixing agent 108 may be located between the at least one protrusion 208 and the carrier 102. Thereby, the squeeze-out may be minimized, while still ensuring that the fixing agent 108 residing in the at least one recess may provide a contact, e.g. an electrically and/or thermally conductive contact, between the recessed surface 214 of the substrate 106 and the carrier 102. In various embodiments, the thickness TF of the fixing agent 108 for the case where the volume V_{FIX} of the fixing agent 108 arranged over the first main surface 1061 may correspond to, in other words be equal to, the total volume V_{REC,total} of the at least one recess 210 may be considered a minimum thickness TFₘᵢₙ, e.g. the minimum thickness TFₘᵢₙ for filling the at least one recess 210 completely.

In various embodiments, the thickness TF of the fixing agent 108 may be chosen such that the amount is larger than described above, e.g. TF>n×A_{REC}×HP/A_{MS1}. In this way, more of the fixing agent 108 may be available than required for filling the at least one recess 210, such that the, e.g. complete, filling of the at least one recess 210 with the fixing agent 108 may be achieved with higher certainty. The fixing agent 108 that may be present in excess of the fixing agent 108 required to fill the at least one recess 210 completely may be referred to as the excess fixing agent. In various embodiments, a difference between the thickness TF of the fixing agent 108 and the minimum thickness TFₘᵢₙ of the fixing agent 108 may be chosen such that the excess fixing agent has a small volume, for example the volume of the excess fixing agent may amount to less than 10% of the volume V_{FIX} of the fixing agent 108, e.g. less than 5%, e.g. less than 1%.

For example in a case where a plurality of protrusions 108 is formed, or where parts, e.g. two parts, of the same protrusion 108, e.g. of a protrusion 108 formed like a ring, run in parallel, a distance DP between the protrusions 108 or the parts of the protrusion 108 may be in a range from about 200 μm to about 1 mm, e.g. about 500 μm.

The at least one protrusion 208 may be formed from the same material as the substrate 106. The at least one protrusion 208 may be formed from a material that is different from the material of the substrate 106, for example from an (e.g. different) semiconductor material, or from a metal.

In various embodiments, as shown in FIG. 2C and FIG. 2D, the substrate 106 may be arranged on a carrier 102, e.g. on a second main surface 1022 of the carrier 102. The second main surface 1022 of the carrier 102 may also be referred to as the contact surface 1022 of the carrier 102 or as the top surface 1022 of the carrier 102, and a side of the carrier 102 on which the second main surface 1022 of the carrier 102 is located may be referred to as the second main side, the second side, the contact side or the top side of the carrier 102. In various embodiments, the carrier 102 may include a first main surface 1021 opposite the second main surface 1022 of the carrier 102. The first main surface 1021 of the carrier 102 may also be referred to as the bottom surface 1021 of the carrier 102, and a side of the carrier 102 on which the first main surface 1021 of the carrier 102 is located may be referred to as the first main side, the first side, or the bottom side of the carrier 102.

The carrier 102 may include or essentially consist of a conductive material, a semiconductive material, and/or a dielectric material. In various embodiments, the carrier 102 may include or essentially consist of a metal. The carrier 102 may for example (but not limited to this) include a metal in a case where the substrate 106 includes or essentially consists of a semiconductor material. The carrier 102 may for example include at least one metal of a group of metals consisting of copper, aluminum, nickel, a copper alloy, a nickel alloy and an aluminum alloy.

The carrier 102 may include or essentially consist of a semiconductor material. The carrier 102 may for example include at least one material from a group of semiconductor materials consisting of silicon, germanium, gallium arsenide, indium antimonide, zinc selenide, and cadmium sulfide, or any other from the group of III-V or II-VI compound semiconductors. The carrier 102 may for example (but not limited to this) include or essentially consist of a semiconductor material in a case where the substrate 106 includes or essentially consists of a metal or a dielectric.

The carrier 102 may include or essentially consist of a dielectric material. The carrier 102 may for example include at least one dielectric material from a group of dielectric materials consisting of ceramics and a polymer. The carrier 102 may for example (but not limited to this) include or essentially consist of a dielectric material in a case where the substrate 106 includes or essentially consists of a semiconductor material.

As shown in FIG. 2C, the substrate 106 with the fixing agent 108 formed on its first main surface 1061, e.g. its structured first main surface 1061, may be arranged on the carrier 102, e.g. on the second main surface of the carrier 1022, using a force F directed towards the carrier 102. In other words, the substrate 106 may be pressed onto the carrier 102 using the force F. The force F may, in various embodiments, be an external force F, for example exerted by a press. In various embodiments, the force F may be exerted by a weight of the substrate 106, e.g. the force F may be the gravitational force.

At least at some point in time while the force F may be exerted on the substrate 106, the fixing agent 108 may be in a viscous state. For example, the fixing agent 108 may be viscous, e.g. with a high viscosity, e.g. with a viscosity in a range from about 1,000 mPa s to about 100,000 mPa s when it is formed on the first main surface 1061 of the substrate 106. This may for example be the case for an adhesive, e.g. a glue. Alternatively, the fixing agent 108 may be solid, i.e. hard, when the substrate 106 is arranged on the carrier 102, and may liquefy, e.g. melt, later, e.g. when the fixing agent 108, e.g. the substrate 106 and the fixing agent 108 or a system including the substrate 106, the carrier 102 and the fixing agent reach(es) a melting temperature of the fixing agent 108.

In various embodiments, the force F acting on the substrate 106 may move the substrate 106 towards the carrier 102 until the at least one protrusion 108 at least partially comes into contact with the second main surface 1022 of the carrier 102. The at least partial contact between the at least one protrusion 108, e.g. its contact surface 212, and the carrier 102 may be shown in FIG. 2D.

In various embodiments, the substrate 106 and the carrier 102 may contact each other at least in a contact region CR. For the substrate 106 shown with the solid outline, the contact region CR may be out of the plane of the cross section. The contact region CR may be essentially point-like, for example in a case where a corner of the substrate 106 on the at least one protrusion 208 may first come into contact with the second main surface 1022 of the substrate. Alternatively, the contact region CR may form a line. The line may for example be an edge of the at least one protrusion 208. For example, the substrate 106 shown as the dashed line in FIG. 2D and the carrier 102 may extend into and/or out of the plane of the paper with their cross-sections unchanged. In that case, the contact region CR may form a line between the edge of the protrusion 208 and the second main surface 1022 of the carrier 102. Alternatively, the contact region CR may form a two-dimensional area. The two-dimensional contact area CR may for example be formed by at least a part of a contact surface 212 of the at least one protrusion 208, by parts of contact surfaces 212 of a plurality of protrusions 208, or by all contact surfaces 212 of all of the plurality of protrusions 208.

When the substrate 106 is arranged on the carrier 102, a space 216 may be formed between the first main surface 1061 of the substrate 106 and the second main surface 1022 of the carrier 102. The space 216 may at least include a space 210 between the recessed surface 214 and the second main surface 1022 of the carrier 102, e.g. the at least one recess 210. The space 216 may additionally include a space formed between at least a part of the at least one contact surface 214 of the at least one protrusion 208 that may not be in contact with the second main surface 1022 of the carrier 102.

The fixing agent 108 may be arranged in the space 216. By way of example, the fixing agent 108 may completely fill the space 216.

The force F may be applied to the substrate 106 until a counter-force acts on the substrate 106, which may be exerted by the carrier 102. In other words, the substrate 106 may be pressed onto the carrier 102 until a resistance is noticed, e.g. until a detector (not shown) detects the counter-force. Alternatively, e.g. in a case where the fixing agent 108 has a low viscosity, the substrate 106 may be given time to settle by itself following gravitational force, e.g. to have the at least one protrusion 108, e.g. the contact surface 212, come into contact with the second main surface 1022 of the carrier 102.

Even though above the force F has been described as acting on the substrate 106 and pressing the substrate 106 onto the carrier 102 (which may remain stationary), the force F may alternatively act in the opposite direction, pressing the carrier 102 onto the substrate 106, while the substrate 106 may remain stationary, or both, the substrate 106 and the carrier 102 may be pressed towards each other, with none of the two remaining stationary.

During the arranging of the substrate 106 on the carrier 102, e.g. during the pressing of the substrate 106 onto the carrier 102, e.g. onto the second main surface 1022 of the carrier 102, at least the fixing agent 108 formed over the at least one protrusion 208 may be displaced. The force F with which the substrate 106 may be pressed onto the carrier 102 may cause a lateral movement, e.g. a movement essentially parallel to the second main surface 1022 of the carrier 102, of at least a part of the fixing agent 108, e.g. of the part of the fixing agent 108 formed over the at least one protrusion 208. At least a fraction of the displaced fixing agent 108 may be moved to the space 216, e.g. to the at least one recess 210 and/or to the space 214 between the part of the contact surface 212 of the at least one protrusion 208 that may not be in contact with the second main surface 1022 of the carrier 102.

In various embodiments, the displacing of at least part of the fixing agent 108 to the space 216 formed between the substrate 106 and the carrier 102 may leave less fixing agent 108 to be pressed out of a region between the first main surface 1061 of the substrate 106 and the second main surface 1022 of the carrier 102.

For a conventional substrate with a flat first main surface, if the pressing force and/or the position of the substrate above the carrier is not controlled very precisely, a situation may occur in which essentially all the fixing agent may be removed from the region between the first main surface of the substrate and the second main surface of the carrier, e.g. because the first main surface of the substrate and the second main surface of the carrier are essentially in full-surface contact. The fixing agent may thereby be dislocated to a region on the carrier outside the substrate, where it would be considered to form a squeeze-out.

The at least one protrusion 208 may act as a spacer preventing an essential full-surface contact of the first main surface 1061 of the substrate 106 and the second main surface 1022 of the carrier 102. Furthermore, the at least one protrusion 208 may act as a barrier against a lateral movement of the fixing agent 108. For example, the force F pressing the substrate 106 onto the carrier 102 may not be able to dislocate, e.g. squeeze or shift, a part of the fixing agent 108 residing in one of the at least one recess 210 to another one of the at least one recess 210. Thereby, an amount of fixing agent available for being squeezed out from a region between the first main surface 1061 of the substrate 106 and the second main surface 1022 of the carrier 102 may be reduced, in other words, less material than in the conventional case with the unstructured substrate may contribute to the squeeze-out of the fixing agent 108.

FIG. 3 shows an analogous example of a substrate 106 to be connected using a method of connecting a substrate according to various embodiments.

For visualization, FIG. 3 shows a photograph of a three-dimensional structured surface that may be structured like an exemplary first main surface 1061 of the substrate 106 as shown in FIG. 2A to FIG. 2D.

In various embodiments, the at least one protrusion 208 may include a plurality of protrusions 208₁, 208₂. The plurality of protrusions 208₁, 208₂ may be shaped as a plurality of walls 208₁, 208₂ that may be arranged as a grid. In other words, the at least one protrusion 208 may include a first set of walls 208₁, for example a set of essentially parallel walls 208₁, and a second set of walls 208₂, for example a set of essentially parallel walls 208₂, arranged at an angle Θ, e.g. at an essentially right angle, to the first set of walls 208₁, and intersecting with the first set of walls 208₁.

A plurality of recesses 210 may be formed between the plurality of protrusions 208₁, 208₂.

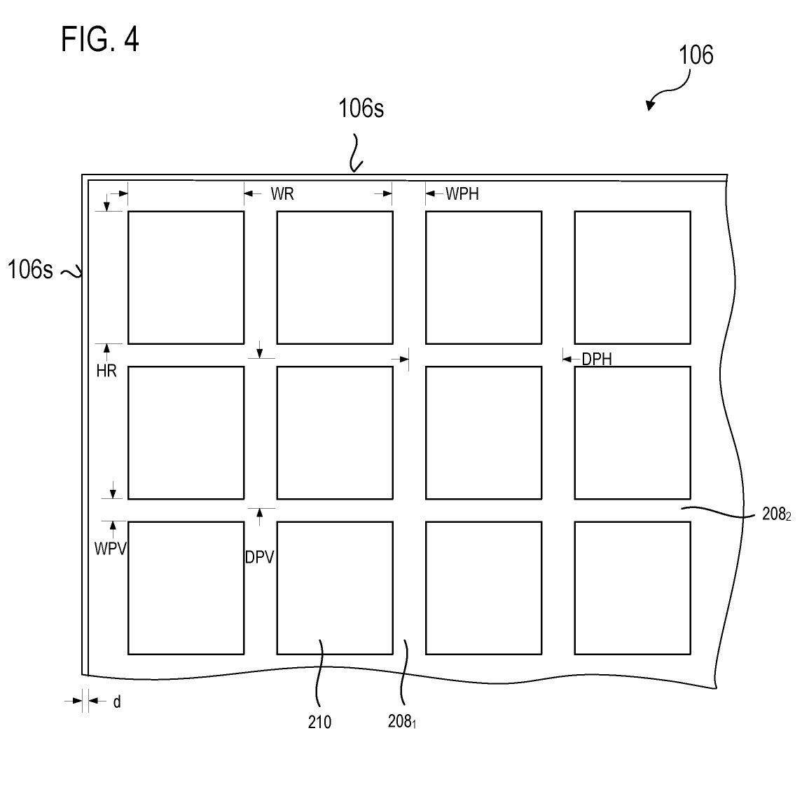

FIG. 4 shows a schematic top view of a substrate 106 to be connected using a method of connecting a substrate according to various embodiments. The substrate 106 may for example be formed as described above in connection with any of the FIG. 2A to FIG. 2D or FIG. 3. Structures, materials, parameters, processes etc. applying to the substrates 106 described there may also apply to the substrate 106 of FIG. 4.

In various embodiments, the substrate may include a plurality of protrusions 208. The protrusions 208 may be shaped as a grid, e.g. as described in context with FIG. 3. The plurality of protrusions may for example include a first set of set of walls 208₁, for example a set of essentially parallel walls 208₁, and a second set of walls 208₂, for example a set of essentially parallel walls 208₂, as described e.g. in context with FIG. 3. A width WPH of the walls 208₁ of the first set of walls 208₁ may be different from a width WPV of the walls 208₂ of the second set of walls 208₂. The width WPH of the walls 208₁ of the first set of walls 208₁ may be the same as the width WPV of the walls 208₂ of the second set of walls 208₂.

The widths WPH and distances DPH of all walls 208₁ of the first set of walls 208₁ may be essentially the same, and the widths WPV and distances DPV of all walls 208₂ of the second set of walls 208₂ may be essentially the same. In that case, the plurality of protrusions 208, consisting of the plurality of walls 208₁, 208₂, may be considered as forming a regular pattern. More generally, in a case where the at least one protrusion 208 includes a plurality of protrusions 208, the plurality of protrusions 208 may be considered as forming a regular pattern if the plurality of protrusions consists of a plurality of subsets of protrusions 208. A configuration of each of the subsets of protrusions 208, e.g. the shapes, orientations, widths and distances of a plurality of protrusions forming the subset of protrusions 208, is essentially identical for the plurality of subsets of protrusions 208.

At least one wall 208₁, 208₂ of the first and the second set of walls 208₁,208₂ may be formed along a side surface 106s of the substrate 106, e.g. with a small distance d between the side surface 106s and the wall 208₁, 208₂. The distance d may for example be a small fraction of the width WPH and/or of the width WPV of the wall, e.g. d may be smaller than 10% of the width WPH and/or of the width WPV, e.g. smaller than 5%, e.g. smaller than 1%. The wall 208₁, 208₂ may be formed flush with the side surface 106s of the substrate 106. The wall 208₁, 208₂ may for example extend essentially or completely along the whole side surface 106s of the substrate 106.

A plurality of recesses 210 may be formed between the walls 208₁, 208₂ of the substrate 106. The recesses 210 may have a width WR between pairs of walls of the first set of walls 208₁, and a height HR between pairs of the second set of walls 208₂. The width WR may be different from the height HR. Alternatively, the width WR of the recesses 210 may be the same as the height HR of the recesses 210.

The width WPH, and/or the width WPV may be different for individual walls of the same set of walls. The distance DPH, and/or the distance DPV may be different for individual pairs of walls of the same set of walls. In various embodiments, the heights HR of the recesses 210 and/or the widths WR of the recesses 210 may vary. Unless the plurality of protrusions 208 can in that case be considered as consisting of a plurality of essentially identical subsets of protrusions 208, the plurality of protrusions may be considered as forming an irregular pattern of protrusions 208.

The widths WPH and WPV of the at least one protrusion 108 may be 104.48 μm, the height HR of each of the plurality of recesses 210 may be 466.72 μm, and the width WR of each of the plurality of recesses 210 may be 403.96 μm.

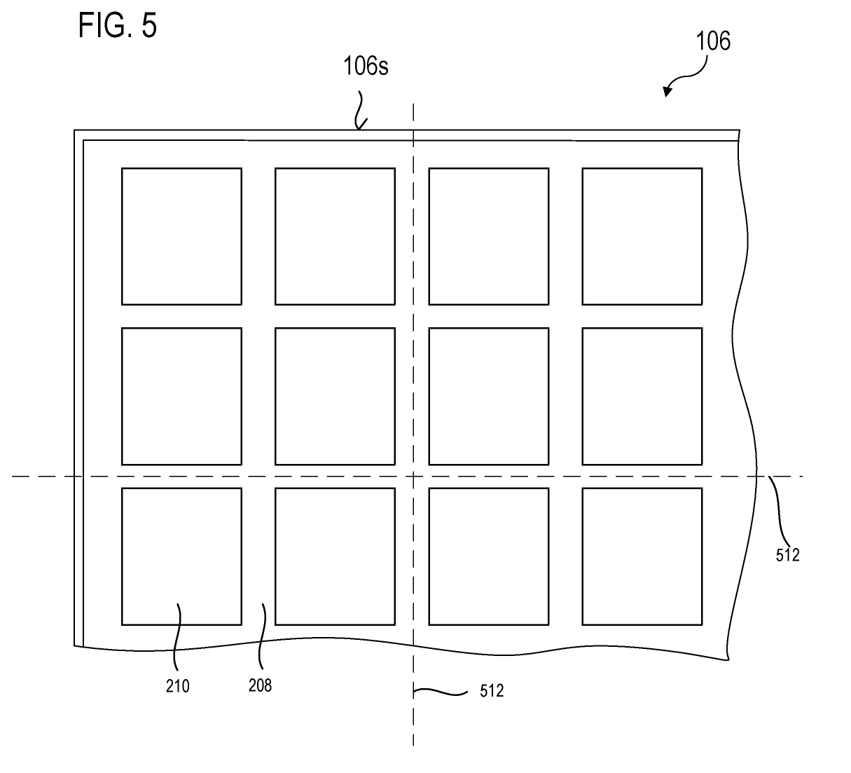

FIG. 5 shows a schematic top view of substrate 106 to be connected using a method of connecting a substrate according to various embodiments.

The substrate 106 may essentially correspond to one or more of the substrate 106 described in various embodiments above.

The substrate 106 may be or include a wafer 106. It may include a plurality of chips and may be separated into the plurality of chips at kerf regions 512.

The at least one protrusion 208 may include a plurality of protrusions 208, for example shaped as a grid as described above.

At least a part of the plurality of protrusions 208 may be formed at the kerf regions 512. In this way, it may be ensured that along each side surface of the chips, at least one protrusion of the plurality of protrusions 208 may be formed, which may act as a final bather restricting a lateral movement of the fixing agent 108. Furthermore, a separation of the wafer into individual chips, e.g. using sawing, may be facilitated, because a thickness of material to be separated, e.g. sawed, may stay the same along the kerf region 512. On each individual chip, a plurality of protrusions may be formed, for example three walls of each set of walls as shown in FIG. 5. The number of protrusions 108 per chip may be different, e.g. only two or four or more per set of walls. Also in a case that the plurality of protrusions 208 have a different shape or arrangement, the number of protrusions per chip may be adjusted.

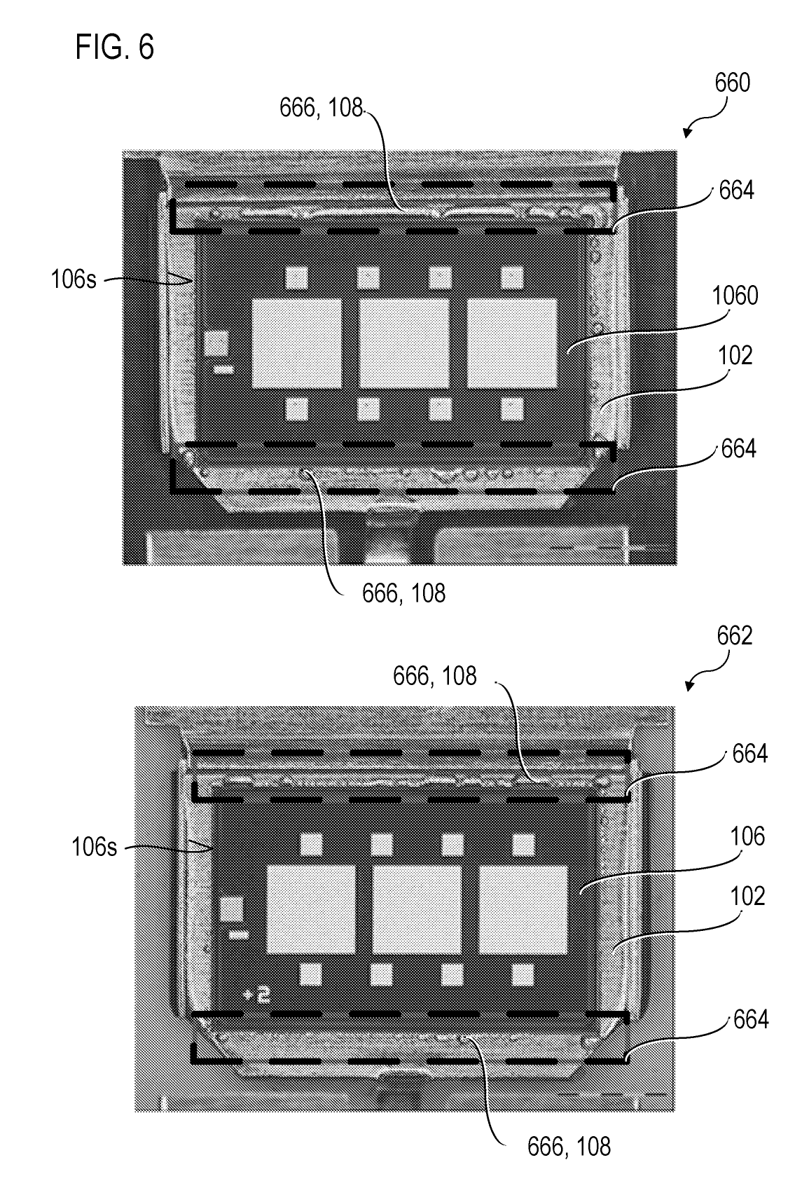

FIG. 6 shows two photographs 660, 662 of top views of substrates 1060, 106 comparing a substrate 106 connected using a method of connecting a substrate according to various embodiments (photograph 662) to a substrate 1060 connected using a conventional method (photograph 660). Parts, methods, parameters etc. may correspond to those described above for the method of connecting a substrate according to various embodiments and for the conventional method of connecting a substrate, respectively.

The substrate may have been chips, and the substrate may have been a copper die pad. In the embodiment, the at least one protrusion 108 may have been formed as a grid of protrusions, for example as shown and described in connection with FIG. 4 and FIG. 5.

As can be seen from FIG. 6, a squeeze-out 666 of fixing agent 108 may be detected in both photographs 660, 662, in particular in regions indicated by boxes 664. The squeeze-out 666, 108 may however be visibly reduced in photograph 662 showing the substrate 106 connected to the substrate 102 using the method of connecting a substrate according to an embodiment.

A quantitative analysis of the squeeze-out is given below:

| | | Without | With | |
|---|---|---|---|---|
| | | grid/lattice | grid/lattice | Difference |
| Vehicle | CoolMos@TO220 | | | |
| Size [μm] | Maximum | 525 | 512 | −3% |
| | Average | 392.3 | 366.9 | −7% |
| | Standard | 62.8 | 67.2 | +7% |
| | deviation | | | |
| Hight [μm] | Maximum | 86 | 69 | −20% |
| | Average | 64.8 | 57.5 | −11% |
| | Standard | 12.0 | 4.5 | −63% |
| | deviation | | | |

As may be seen from the statistical analysis and comparison of the squeeze-out 666, 108, an amount of squeeze-out 666, 108, both in a size, which may be a maximum distance that the squeeze-out may reach from the side surface 106s of the substrate 106, and a height of the squeeze-out 666, 108, which may be a height of the squeeze-out 666, 108 above the surface of the carrier 106, may be reduced using the backside structuring, i.e. the grid/lattice of the substrate 106 according to the embodiment.

The height of the squeeze-out 666, 108 may be a dominant parameter for a volume contained in the squeeze-out 666, 108. By substantially reducing it (reduction of 20% of the maximum value, and of 11% of the average value in the embodiment), the volume of the squeeze-out 666, 108 may be reduced by a substantial amount. A standard deviation of the height of the squeeze-out 666, 108 may be reduced by 63% in the embodiment. Thereby, a squeeze-out behaviour may be more reproducible.

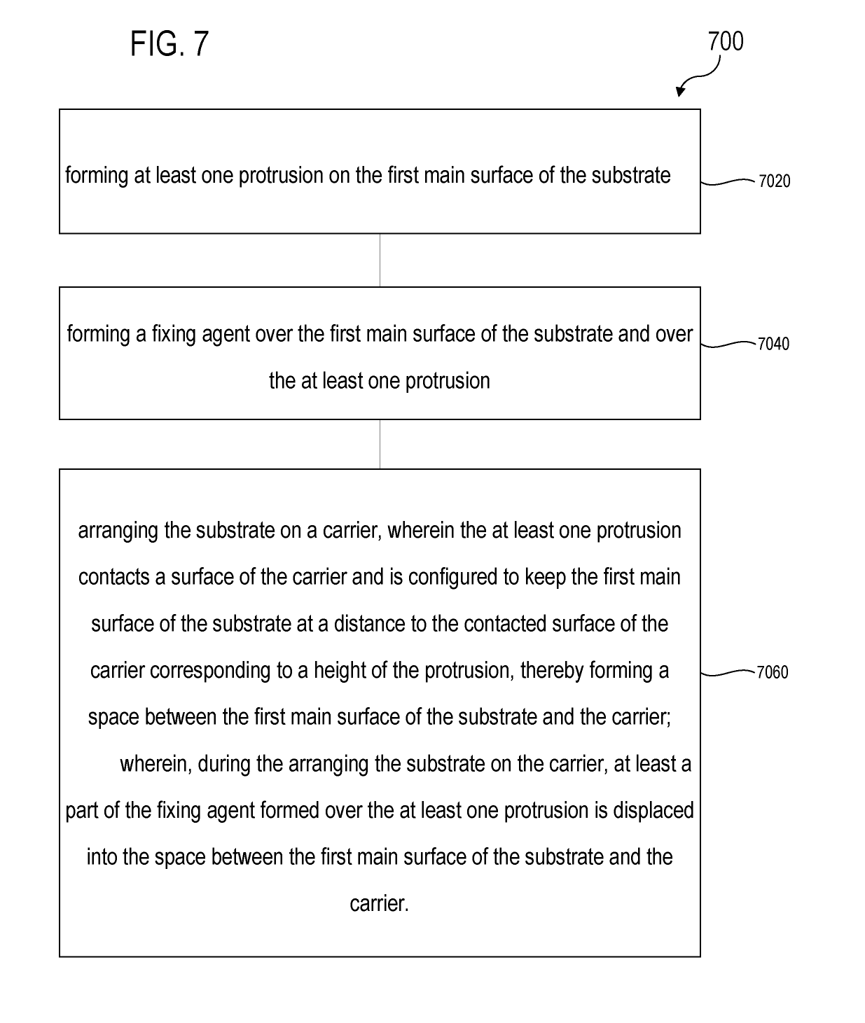

FIG. 7 shows a process flow for a method 700 of connecting a substrate according to various embodiments.

In various embodiments, the method of connecting a substrate may include forming at least one protrusion on a first main surface of the substrate (in 7020). The method may further include forming a fixing agent over the first main surface of the substrate and over the at least one protrusion (in 7040); and arranging the substrate on a carrier. The at least one protrusion may contact a surface of the carrier and may be configured to keep the first main surface of the substrate at a distance to the contacted surface of the carrier corresponding to a height of the protrusion, thereby forming a space between the first main surface of the substrate and the carrier. During the arranging the substrate on the carrier, at least a part of the fixing agent formed over the at least one protrusion may be displaced into the space between the first main surface of the substrate and the carrier (in 7060).

A method of connecting a substrate is provided. The substrate may include a first main surface and a second main surface opposite the first main surface. The method may include forming at least one protrusion on the first main surface of the substrate; forming a fixing agent over the first main surface of the substrate and over the at least one protrusion; and arranging the substrate on a carrier. The at least one protrusion may contact a surface of the carrier and may be configured to keep the first main surface of the substrate at a distance to the contacted surface of the carrier corresponding to a height of the protrusion, thereby forming a space between the first main surface of the substrate and the carrier. During the arranging the substrate on the carrier, at least a part of the fixing agent formed over the at least one protrusion may be displaced into the space between the first main surface of the substrate and the carrier. The substrate includes a semiconductor material.

In various embodiments, the semiconductor material may include at least one material selected from a group of materials consisting of silicon; germanium; gallium arsenide; indium antimonide; zinc selenide; and cadmium sulfide; or any other from the group of III-V or II-VI compound semiconductor.

In various embodiments, the forming of the at least one protrusion on the first main surface of the substrate may include forming a structure comprising a plurality of walls on the first main surface of the substrate. The plurality of walls may define at least one recess between them.

In various embodiments, the structure may be formed as a regular pattern.

In various embodiments, the substrate may include at least one chip. In various embodiments, the plurality of walls may be formed at least along a circumference of the at least one chip.

In various embodiments, the substrate may be a wafer.

The method may further include, before the arranging of the substrate on the carrier, separating the substrate into individual chips.

The walls may be formed in kerf regions of the substrate.

The forming of the fixing agent over the first main surface of the substrate and over the at least one protrusion may include completely covering the first main surface of the substrate and the at least one protrusion with the fixing agent.

In various embodiments, the fixing agent may include a solder.

The solder may be a diffusion solder.

In various embodiments, the solder may be one of Sn, In, Zn, Sn, Bi, Ga or a binary combination of these like AuSn, SnAg, InSn, AuIn, ZnSn, BiZn, BiSn, possibly with trace amounts of additional 3^{rd}, 4^{th} or 5^{th} elements.

The method may further include, before the forming of the fixing agent over the first main surface of the substrate and over the at least one protrusion, forming a first material on the first main surface of the substrate.

The first material may include at least one of Al, Ti, As, Au and Cr.

In various embodiments, the method may further include before the forming of the fixing agent over the first main surface of the substrate and over the at least one protrusion, forming a second material on the main surface of the substrate.

The second material may include at least one of Ti, W, TiW, TiN, Ta, TaN, and Co. In various embodiments, the second material is formed over the first material.

In various embodiments, the method may further include forming a further material over the carrier.

In various embodiments, the method may further include fixing the substrate to the carrier by the fixing agent.

In various embodiments, a chip assembly may be provided. The chip assembly may include a carrier; a chip including a first main surface; a second main surface opposite the first main surface; and at least one protrusion formed on the first main surface of the chip. The chip may be arranged with the at least one protrusion contacting the carrier, such that the main surface of the substrate has a distance to the carrier corresponding to a height of the protrusion, thereby forming a space between the main surface of the chip and the carrier. The chip assembly may further include a fixing agent, fixing the first main surface of the chip to the carrier. A portion of the fixing agent may be arranged in the space. In various embodiments, the carrier may be a lead frame.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of connecting a substrate, the substrate comprising a first main surface and a second main surface opposite the first main surface, the method comprising:
forming at least one protrusion on the first main surface of the substrate;
forming a fixing agent over the first main surface of the substrate and over the at least one protrusion; and
arranging the substrate on a carrier, wherein the at least one protrusion contacts a surface of the carrier and is configured to keep the first main surface of the substrate at a distance to the contacted surface of the carrier corresponding to a height of the protrusion, thereby forming a space between the first main surface of the substrate and the carrier;
wherein, during the arranging the substrate on the carrier, at least a part of the fixing agent formed over the at least one protrusion is displaced into the space between the first main surface of the substrate and the carrier.

2. The method of claim 1,
wherein the substrate comprises a semiconductor material.

3. The method of claim 2,
wherein the semiconductor material comprises at least one material selected from a group of materials consisting of:
silicon;
silicon carbide;
germanium;
a III-V compound semiconductor; and
a II-VI compound semiconductor.

4. The method of claim 1,
wherein the forming of the at least one protrusion on the first main surface of the substrate comprises forming a structure comprising a plurality of walls on the first main surface of the substrate, wherein the plurality of walls define at least one recess between them.

5. The method of claim 4,
wherein the structure is formed as a regular pattern.

6. The method of claim 1,
wherein the substrate comprises at least one chip.

7. The method of claim 4,
wherein the plurality of walls is formed at least along a circumference of the at least one chip.

8. The method of claim 1,
wherein the substrate is a wafer.

9. The method of claim 8, further comprising:
before the arranging of the substrate on the carrier, separating the substrate into individual chips.

10. The method of claim 9,
wherein the forming of the at least one protrusion on the first main surface of the substrate comprises forming a structure comprising a plurality of walls on the first main surface of the substrate, wherein the plurality of walls define at least one recess between them;
wherein the walls are formed in kerf regions of the substrate.

11. The method of claim 1,
wherein the forming of the fixing agent over the first main surface of the substrate and over the at least one protrusion comprises completely covering the first main surface of the substrate and the at least one protrusion with the fixing agent.

12. The method of claim 1,
wherein the fixing agent comprises a solder.

13. The method of claim 12,
wherein the solder is a diffusion solder.

14. The method of claim 12,
wherein the solder is one of Sn, In, Zn, Bi, Ga or a binary combination of these like AuSn, SnAg, InSn, AuIn, ZnSn, BiZn, BiSn.

15. The method of claim 14,
wherein the solder includes trace amounts of additional 3^{rd}, 4^{th}, or 5^{th} elements.

16. The method of claim 1, further comprising:
before the forming of the fixing agent over the first main surface of the substrate and over the at least one protrusion, forming a first material on the first main surface of the substrate.

17. The method of claim 16,
wherein the first material comprises at least one of Al, Ti, Au, As and Cr

18. The method of claim 1, further comprising:
before the forming of the fixing agent over the first main surface of the substrate and over the at least one protrusion, forming a second material on the main surface of the substrate.

19. The method of claim 18,
wherein the second material comprises at least one of Ti, W, TiW, TiN, Ta, TaN, and Co.

20. The method of claim 18,
wherein the second material is formed over the first material.

21. The method of claim 1, further comprising:
forming a further material over the carrier.

22. The method of claim 1, further comprising:
fixing the substrate to the carrier by the fixing agent.

23. A chip assembly, comprising:
a carrier;
a chip comprising
a first main surface;
a second main surface opposite the first main surface; and
at least one protrusion formed on the first main surface of the chip;
wherein the chip is arranged with the at least one protrusion contacting the carrier, such that the first main surface of the substrate has a distance to the carrier corresponding to a height of the protrusion, thereby forming a space between the first main surface of the chip and the carrier; and
a fixing agent, fixing the first main surface of the chip to the carrier, wherein a portion of the fixing agent is arranged in the space.

24. The chip assembly of claim 23,
wherein the carrier is a lead frame.
